(19) United States
(12) Patent Application Publication
(10) Pub. No.: US 2025/0116810 A1
(43) Pub. Date: Apr. 10, 2025

(54) SEMICONDUCTOR PACKAGE WITH PHOTONICS CHIP

(71) Applicant: SAMSUNG ELECTRONICS CO., LTD., Suwon-si (KR)

(72) Inventors: Daegon Kim, Suwon-si (KR); Junghoon Kang, Suwon-si (KR)

(21) Appl. No.: 18/887,727

(22) Filed: Sep. 17, 2024

(30) Foreign Application Priority Data
Oct. 10, 2023 (KR) 10-2023-0134365

(51) Int. Cl. G02B 6/12; G02B 6/13; H01L 23/00; H01L 23/538; H01L 25/16

(52) U.S. Cl. CPC G02B 6/12004; G02B 6/13; H01L 23/5384; H01L 25/167; H01L 24/16; H01L 24/17; H01L 2224/16145; H01L 2224/16227; H01L 2224/17181

(57) ABSTRACT

A semiconductor package includes an interposer including an interposer optical waveguide, and a plurality of chiplets coupled onto the interposer and each including a semiconductor chip and a photonics chip electrically coupled to the semiconductor chip, wherein the photonics chip includes a photonic integrated circuit configured to input or output an optical signal, and an optical waveguide optically coupled to the interposer optical waveguide.

### CROSS-REFERENCE TO RELATED APPLICATION

This application claims priority under 35 U.S.C. § 119 to Korean Patent Application No. 10-2023-0134365, filed on Oct. 10, 2023, in the Korean Intellectual Property Office, the disclosure of which is incorporated by reference herein in its entirety.

### BACKGROUND

Aspects of this disclosure relate to semiconductor packages including photonics chips.

Semiconductor packaging may improve the functioning of electronic devices and integrate components together. A semiconductor package may include various integrated circuits, such as memory chips or logic chips, mounted on a package substrate. As data traffic has grown in data centers and communications infrastructure, semiconductor packaging can provide benefits for communication.

### SUMMARY

Some aspects of this disclosure relate to a semiconductor package that includes a plurality of semiconductor chips and separately attaches a photonics chip to each of the plurality of semiconductor chips.

Some aspects of this disclosure relate to a semiconductor package including an interposer connecting a plurality of photonics chips to each other.

Additional aspects will be set forth in and be apparent from the following description.

In some implementations, there is provided a semiconductor package including an interposer including an interposer optical waveguide, and a plurality of chiplets coupled onto the interposer and each including a semiconductor chip and a photonics chip electrically coupled to the semiconductor chip, wherein the photonics chip includes a photonic integrated circuit configured to input or output an optical signal, and an optical waveguide optically coupled to the interposer optical waveguide.

In some implementations, there is provided a method of manufacturing a semiconductor package, the method including preparing a first chiplet by attaching a first semiconductor chip to a first photonics chip including a first photonic integrated circuit and a first optical waveguide, preparing a second chiplet by attaching a second semiconductor chip to a second photonics chip including a second photonic integrated circuit and a second optical waveguide, preparing an interposer including an interposer optical waveguide, and attaching the first chiplet and the second chiplet to the interposer.

In some implementations, there is provided a semiconductor package including an interposer including an interposer optical waveguide, a first chiplet coupled onto the interposer and including a first semiconductor chip and a first photonics chip electrically coupled to the first semiconductor chip, and a second chiplet coupled onto the interposer and including a second semiconductor chip and a second photonics chip electrically coupled to the second semiconductor chip, wherein the first photonics chip includes a first photonic integrated circuit configured to convert between an electrical signal and an optical signal, a first electronic integrated circuit configured to electrically connect the first semiconductor chip and the first photonic integrated circuit to each other, and a first optical waveguide optically coupled to the interposer optical waveguide, and wherein the second photonics chip includes a second photonic integrated circuit configured to convert between an electrical signal and an optical signal, a second electronic integrated circuit configured to electrically connect the second semiconductor chip and the second photonic integrated circuit, and a second optical waveguide optically coupled to the interposer optical waveguide.

### BRIEF DESCRIPTION OF THE DRAWINGS

Implementations will be more clearly understood from the following detailed description taken in conjunction with the accompanying drawings in which:

FIG. 1 is a side view illustrating an example of a semiconductor package according to some implementations;

FIG. 2 is an enlarged cross-sectional view of a portion of FIG. 1;

FIGS. 3 to 7 are schematic cross-sectional views illustrating an example of a method of manufacturing a semiconductor package, according to some implementations;

FIG. 8 is a graph illustrating an effect of a semiconductor package according to some implementations;

FIG. 9 is a side view illustrating an example of a semiconductor package according to some implementations; and

FIG. 10 is a side view illustrating an example of a semiconductor package according to some implementations.

### DETAILED DESCRIPTION

Hereinafter, various examples will be described in detail with reference to the accompanying drawings. In the drawings, the same elements are denoted by the same reference numerals, and a repeated explanation thereof will not be given.

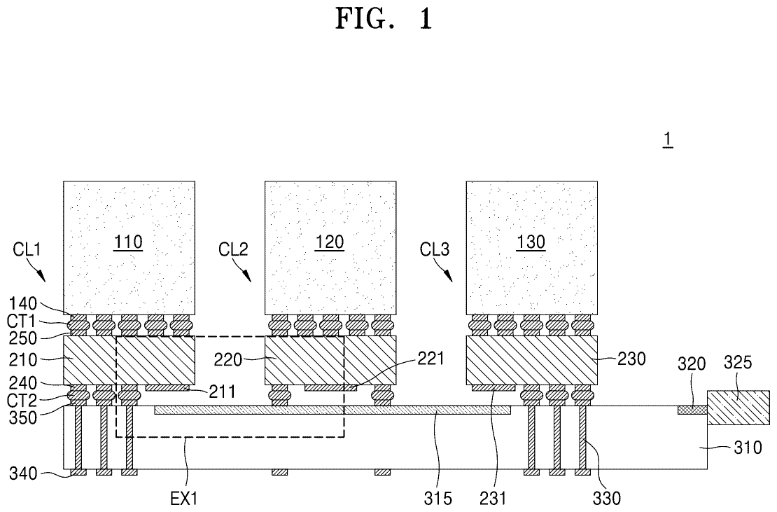

FIG. 1 is a side view illustrating a semiconductor package according to some implementations.

Referring to FIG. 1, a semiconductor package 1 may include a first chiplet CL1, a second chiplet CL2, a third chiplet CL3, and an interposer 310. The first chiplet CL1 may include a first semiconductor chip 110 and a first photonics chip 210. The second chiplet CL2 may include a second semiconductor chip 120 and a second photonics chip 220. The third chiplet CL3 may include a third semiconductor chip 130 and a third photonics chip 230. FIG. 1 illustrates a case in which the semiconductor package 1 includes three chiplets, but the scope of this disclosure is not limited thereto. For example, the semiconductor package 1 may include two or fewer chiplets or may include four or more chiplets.

The first to third semiconductor chips 110, 120, and 130 may each include a memory chip, a system on chip (SoC), a logic chip, and/or a power management integrated circuit (PMIC) chip. The memory chip may include a DRAM chip, an SRAM chip, an MRAM chip, and/or a NAND flash memory chip. The logic chip may include an application processor (AP), a microprocessor, a central processing unit (CPU), a controller, or an application specific integrated circuit (ASIC).

In some implementations, the first photonics chip 210, the second photonics chip 220, and the third photonics chip 230 may each include a photonic integrated circuit (PIC) and an electronic integrated circuit (EIC). The PIC may input and output an optical signal. The EIC may electrically connect a semiconductor chip and the PIC to each other.

The first semiconductor chip 110 may be connected to the first photonics chip 210. The first semiconductor chip 110 may include a plurality of lower pads 140. The plurality of lower pads 140 may include copper, nickel, stainless steel or beryllium copper. A plurality of first connection terminals CT1 may be attached to the plurality of lower pads 140 of the first semiconductor chip 110. The plurality of first connection terminals CT1 may be formed from a solder ball or a solder bump, for example.

The first photonics chip 210 may include a plurality of first upper connection pads 250 and a plurality of first lower connection pads 240. The plurality of first upper connection pads 250 and the plurality of first lower connection pads 240 may each include copper, nickel, stainless steel, or beryllium copper. The plurality of first connection terminals CT1 may electrically and physically connect the lower pad 140 of the first semiconductor chip 110 and the first upper connection pad 250 of the first photonics chip 210 to each other.

The first photonics chip 210 may include a first optical waveguide 211. The first optical waveguide 211 may be disposed below the first photonics chip 210. The first optical waveguide 211 may be disposed to face the interposer 310 below the first photonics chip 210. However, a position of the first optical waveguide 211 is not limited thereto, and the first optical waveguide 211 may be arranged in/on the first photonics chip 210 in various positions in different implementations.

The second semiconductor chip 120 may be connected to the second photonics chip 220. The second semiconductor chip 120 may include the plurality of lower pads 140. The plurality of lower pads 140 may include copper, nickel, stainless steel or beryllium copper. The plurality of first connection terminals CT1 may be attached to the plurality of lower pads 140 of the second semiconductor chip 120. The plurality of first connection terminals CT1 may be formed from a solder ball or a solder bump, for example.

The second photonics chip 220 may include the plurality of first upper connection pads 250 and the plurality of first lower connection pads 240. The plurality of first upper connection pads 250 and the plurality of first lower connection pads 240 may each include copper, nickel, stainless steel, or beryllium copper. The plurality of first connection terminals CT1 may electrically and physically connect the lower pad 140 of the second semiconductor chip 120 and the first upper connection pad 250 of the second photonics chip 220 to each other.

The second photonics chip 220 may include a second optical waveguide 221. The second optical waveguide 221 may be disposed below the second photonics chip 220. The second optical waveguide 221 may be disposed to face the interposer 310 below the second photonics chip 220. However, a position of the second optical waveguide 221 is not limited thereto, and the second optical waveguide 221 may be arranged in/on the second photonics chip 220 in various positions in different implementations.

The third semiconductor chip 130 may be connected to the third photonics chip 230. The third semiconductor chip 130 may include the plurality of lower pads 140. The plurality of lower pads 140 may include copper, nickel, stainless steel or beryllium copper. The plurality of first connection terminals CT1 may be attached to the plurality of lower pads 140 of the third semiconductor chip 130. The plurality of first connection terminals CT1 may be formed from a solder ball or a solder bump, for example.

The third photonics chip 230 may include the plurality of first upper connection pads 250 and the plurality of first lower connection pads 240. The plurality of first upper connection pads 250 and the plurality of first lower connection pads 240 may each include copper, nickel, stainless steel, or beryllium copper. The plurality of first connection terminals CT1 may electrically and physically connect the lower pad 140 of the third semiconductor chip 130 and the first upper connection pad 250 of the third photonics chip 230 to each other.

The third photonics chip 230 may include a third optical waveguide 231. The third optical waveguide 231 may be disposed below the third photonics chip 230. The third optical waveguide 231 may be disposed to face the interposer 310 below the third photonics chip 230. However, a position of the third optical waveguide 231 is not limited thereto, and the third optical waveguide 231 may be arranged in/on the third photonics chip 230 in various positions in different implementations. In some implementations, the first optical waveguide 211, the second optical waveguide 221, and the third optical waveguide 231 may each be a silicon optical waveguide, but implementations are not limited thereto.

The interposer 310 may include a plurality of second upper connection pads 350, a plurality of second lower connection pads 340, and a through via 330. The plurality of second upper connection pads 350 may be connected to the first chiplet CL1 through a plurality of second connection terminals CT2. The plurality of second upper connection pads 350 may be connected to the second chiplet CL2 through the plurality of second connection terminals CT2. The plurality of second upper connection pads 350 may be connected to the third chiplet CL3 through the plurality of second connection terminals CT2. The interposer 310 may be electrically and physically connected to the first chiplet CL1, the second chiplet CL2, and the third chiplet CL3 through the plurality of second upper connection pads 350.

In some implementations, a horizontal (e.g., lateral, in a plan view) area of each of the first chiplet CL1, the second chiplet CL2, and the third chiplet CL3 may be less than a horizontal area of the interposer 310. For example, a horizontal area of each of the first photonics chip 210, the second photonics chip 220, and the third photonics chip 230 may be less than a horizontal area of the interposer 310.

An external connection terminal configured to electrically and physically connect the interposer 310 to an external device on which the interposer 310 is mounted may be attached to the plurality of second lower connection pads 340.

The interposer 310 may include a substrate and the through via 330 formed to pass through the substrate. For example, the substrate may include glass, and the through via 330 may include a through glass via (TGV). However, the substrate is not limited thereto, the substrate may include silicon, and the through via 330 may include a through silicon via (TSV).

The interposer 310 may further include a redistribution structure. The redistribution structure may be located on an upper surface or a lower surface of the substrate of the interposer 310. The redistribution structure located on the upper surface of the substrate of the interposer 310 is referred to as an upper redistribution structure, and the redistribution structure located on the lower surface of the substrate of the interposer 310 is referred to as a lower redistribution structure.

The upper redistribution structure and the lower redistribution structure may each include at least one redistribution insulating layer and a plurality of redistribution patterns. The redistribution insulating layer may include an organic insulating material. For example, the redistribution insulating layer may include a photo imageable dielectric (PID) such as polyimide.

The plurality of redistribution patterns may include a plurality of redistribution lines and a plurality of redistribution vias. The plurality of redistribution patterns may include, for example, metal such as copper (Cu), aluminum (Al), tungsten (W), titanium (Ti), tantalum (Ta), indium (In), molybdenum (Mo), manganese (Mn), cobalt (Co), tin (Sn), nickel (Ni), magnesium (Mg), rhenium (Rc), beryllium (Be), gallium (Ga), ruthenium (Ru) or an alloy of one or more of these and/or other metals, but are not limited thereto.

The redistribution via and the redistribution line of the upper redistribution structure may be electrically connected to the second upper connection pad 350 of the interposer 310. The redistribution via and the redistribution line of the lower redistribution structure may be electrically connected to the second lower connection pad 340 of the interposer 310.

The interposer 310 may include an interposer optical waveguide 315. The interposer optical waveguide 315 may be disposed at an upper end of the interposer 310. The interposer optical waveguide 315 may be disposed to face to first photonics chip 210 to the third photonics chip 230 at the upper end of the interposer 310. The interposer optical waveguide 315 may be buried at the upper end of the interposer 310. For example, the upper surface of the interposer optical waveguide 315 may define the same plane as the upper surface of the interposer 310. However, a position of the interposer optical waveguide 315 is not limited thereto and, the interposer optical waveguide 314 may be arranged in various positions, for example, buried below the upper surface of the interposer 310 or provided at least partially above the upper surface of other portions of the interposer 310. In some implementations, the interposer optical waveguide 315 may include an ionic injection optical waveguide, but the interposer optical waveguide 315 is not limited thereto.

In some implementations, the first chiplet CL1, the second chiplet CL2, and the third chiplet CL3 may transmit and/or receive optical signals to and/or from each other by using the interposer optical waveguide 315. For example, the interposer optical waveguide 315 and the first optical waveguide 211 may transmit and/or receive the optical signals to and/or from each other. The interposer optical waveguide 315 and the second optical waveguide 221 may transmit and/or receive the optical signals to and/or from each other. The interposer optical waveguide 315 and the third optical waveguide 231 may transmit and/or receive the optical signals to and/or from each other. The first photonics chip 210, the second photonics chip 220, and third photonics chip 230 may transmit and/or receive the optical signals to and/or from each other by using the interposer 310 having a large area, including the interposer optical waveguide 315.

In some implementations, the first semiconductor chip 110, the second semiconductor chip 120, and third semiconductor chip 130 may be electrically and optically connected to each other. For example, an electrical signal generated from the first semiconductor chip 110 may be converted into an optical signal by the first photonics chip 210. The optical signal may be input to the second photonics chip 220 through the first optical waveguide 211, the interposer optical waveguide 315, and the second optical waveguide 221. The second photonics chip 220 may convert the optical signal into an electrical signal and output the electrical signal to the second semiconductor chip 120.

In some implementations, one semiconductor chip of the semiconductor package 1 may be attached to one photonics chip, thereby improving the yield of the semiconductor package 1. For example, the first semiconductor chip 110 is attached to the first photonics chip 210. It may be possible to effectively detect defects by individually inspecting each small-sized photonics chip (e.g., the first photonics chip 210 to the third photonics chip 230). Mass production of the semiconductor package 1 may be improved.

The first photonics chip 210, the second photonics chip 220, and the third photonics chip 230 may each include the PIC and the EIC. Because the first photonics chip 210, the second photonics chip 220, and the third photonics chip 230 may each include the PIC, the first photonics chip 210, the second photonics chip 220, and the third photonics chip 230 may have high process complexity and process costs compared with other semiconductor chips. Accordingly, yield may be improved compared to checking defects of a large-sized single photonics chip by individually checking defects of a plurality of small-sized photonics chips. Then, each small-sized photonics chip may be attached to a semiconductor chip individually, thereby reducing defects in the semiconductor package 1 and improving the yield of the semiconductor package 1.

The semiconductor package 1 may further include a connection optical waveguide 320 and an optical fiber 325. The optical fiber 325 may receive an optical signal through the connection optical waveguide 320 and transfer the optical signal to the outside. The optical fiber 325 may transfer the optical signal received from the outside to the connection optical waveguide 320. The connection optical waveguide 320 may transmit and receive an optical signal to and/or from the interposer optical waveguide 315.

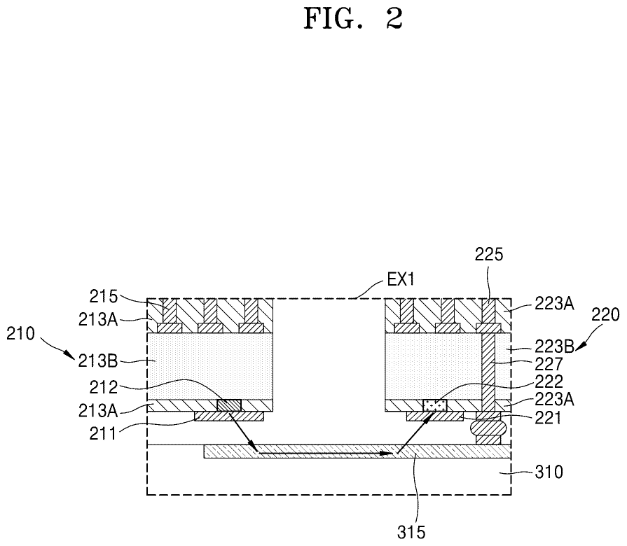

FIG. 2 is an enlarged cross-sectional view of a portion EX1 of FIG. 1.

Referring to FIG. 2, the first photonics chip 210 may include a first substrate 213B, a first insulating layer 213A, and a first wiring structure 215. The first photonics chip 210 may include a PIC and an EIC.

In some implementations, the first substrate 213B may include a semiconductor material such as silicon (Si). In some implementations, the first substrate 213B may include a semiconductor material such as germanium (Ge).

In some implementations, the first substrate 213B may include a silicon on insulator (Sol) structure. For example, the first substrate 213B may include a buried oxide layer (BOX). The first substrate 213B may include various device separation structures such as a shallow trench isolation (STI) structure.

The first substrate 213B may include an active surface on which a plurality of individual devices are formed, and an inactive surface facing the active surface. The first wiring structure 215 may be formed on the active surface of the first substrate 213B. A first through via may extend to the active surface of the first substrate 213B from the inactive surface of the first substrate 213B. In some implementations, the first through via may be electrically connected to the first wiring structure 215 and/or the plurality of individual devices on the active surface of the first substrate 213B.

The first wiring structure 215 may include a plurality of first wiring patterns, a plurality of first wiring vias connected to the plurality of first wiring patterns, and the first insulating layer 213A surrounding the plurality of first wiring patterns and the plurality of first wiring vias. In some implementations, the first wiring structure 215 may have a multilayer wiring structure including the first wiring patterns and the first wiring vias that are located at different vertical levels.

In some implementations, the first substrate 213B may include a PIC and an EIC. In addition, the first substrate 213B may further include a plurality of individual devices of various types. For example, the plurality of individual devices may include various micro electronic devices, for example, an image sensor such as a complementary metal-oxide semiconductor (CMOS) transistor, a metal-oxide-semiconductor filed effect transistor (MOSFET), system large scale integration (LSI), and a CMOS imaging sensor (CIS), a micro-electro-mechanical system (MEMS), an active device, and/or a passive device.

In some implementations, the EIC may include a plurality of devices used for the PIC to interface with other devices. The plurality of devices of the EIC may be located on the active surface of the first substrate 213B. For example, the EIC may include CMOS drivers and transimpedance amplifiers to perform a function such as controlling high frequency signaling of the PIC.

In some implementations, the PIC may include a first optical-electrical converter 212. The PIC may input and output an optical signal. In detail, the PIC may convert an electrical signal into an optical signal using the first optical-electrical converter 212, transmit the optical signal to the first optical waveguide 211, convert an optical signal transmitted from the first optical waveguide 211 into an electrical signal, and transfer the electrical signal to the EIC.

In some implementations, the EIC and the PIC may be electrically connected to each other. In some implementations, the EIC and the PIC may be electrically connected to each other on separate substrates. For example, an EIC chip including an EIC and a PIC chip including a PIC may be connected to each other in a horizontal direction. An EIC chip including the EIC and a PIC chip including the PIC may instead or additionally be stacked on each other and connected to each other in a vertical direction.

The first optical-electrical converter 212 may convert an optical signal into an electrical signal and convert an electrical signal into an optical signal. In some implementations, the first optical-electrical converter 212 may include a photodetector, an optical diode, and a modulator.

In a process in which the optical signal is input to a PIC, the photodetector may detect the optical signal input to the PIC. The optical signal may be detected by the photodetector and converted into an electrical signal. The electrical signal converted by the photodetector may be transferred to a plurality of devices of the first substrate 213B.

In a process in which the PIC outputs the optical signal, the plurality of devices of the first substrate 213B may transfer the electrical signal to the modulator. The modulator may input a signal to light emitted from an optical diode according to the electrical signal (e.g., may modulate the emitted light according to the electrical signal) to convert the electrical signal into an optical signal.

In some implementations, the first optical waveguide 211 may be optically connected to the interposer optical waveguide 315. In this case, the first optical waveguide 211 and the interposer optical waveguide 315 may be connected to each other via evanescent coupling, but the coupling is not limited thereto. For example, the first optical waveguide 211 and the interposer optical waveguide 315 may also be connected to each other via edge coupling and grating coupling.

In FIG. 2, the first optical-electrical converter 212 is shown to be buried in the first insulating layer 213A, but the arrangement not limited thereto, and, for example, the first optical-electrical converter 212 may be covered by an oxide layer separate from the first insulating layer 213A. For example, an oxide layer may be formed at one side of the first insulating layer 213A, and the first optical-electrical converter 212 may be located inside the oxide layer.

In some implementations, the second substrate 223B may include a semiconductor material such as silicon (Si). In some implementations, the second substrate 223B may include a semiconductor material such as germanium (Ge).

In some implementations, the second substrate 223B may include a silicon on insulator (Sol) structure. For example, the second substrate 223B may include a BOX. The second substrate 223B may include various device separation structures such as an ST1 structure.

The second substrate 223B may include an active surface on which a plurality of individual devices are formed and an inactive surface facing the active surface. A second wiring structure 225 may be formed on the active surface of the second substrate 223B. A second through via 227 may extend to the active surface of the second substrate 223B from the inactive surface of the second substrate 223B. In some implementations, the second through via 227 may be electrically connected to the second wiring structure 225 and/or the plurality of individual devices on the active surface of the second substrate 223B.

The second wiring structure 225 may include a plurality of second wiring patterns, a plurality of second wiring vias connected to the plurality of second wiring patterns, and a second insulating layer 223A surrounding the plurality of second wiring patterns and the plurality of second wiring vias. In some implementations, the second wiring structure 225 may have a multilayer wiring structure including the second wiring patterns and the second wiring via that are located at different vertical levels.

In some implementations, the second substrate 223B may include a PIC and an EIC. The second substrate 223B may further include a plurality of individual devices of various types. For example, the plurality of individual devices may include various micro electronic devices, for example, an image sensor such as a complementary metal-oxide semiconductor (CMOS) transistor, a metal-oxide-semiconductor filed effect transistor (MOSFET), system large scale integration (system LSI), and a CMOS imaging sensor (CIS), a MEMS, an active device, and/or a passive device.

In some implementations, the EIC may include a plurality of devices used for the PIC to interface with other devices. The plurality of devices of the EIC may be located on the active surface of the second substrate 223B. For example, the EIC may include CMOS drivers and transimpedance amplifiers to perform a function such as controlling high frequency signaling of the PIC.

In some implementations, the PIC may include a second optical-electrical converter 222. The PIC may input and output an optical signal using the second optical-electrical converter 222. For example, the PIC may convert an electrical signal into an optical signal, transfer the optical signal to the second optical waveguide 221, convert an optical signal transmitted from the second optical waveguide 221 into an electrical signal, and transfer the electrical signal to the EIC.

In some implementations, the EIC and the PIC may be electrically connected to each other. Although not shown in FIG. 2, the EIC and the PIC may be electrically connected to each other on separate substrates. For example, an EIC chip including an EIC and a PIC chip including a PIC may be connected to each other in a horizontal direction. An EIC chip including the EIC and the PIC chip including the PIC may instead or additionally be stacked on each other and connected to each other in a vertical direction.

The second optical-electrical converter 222 may convert an optical signal into an electrical signal and convert an electrical signal into an optical signal. In some implementations, the second optical-electrical converter 222 may include a photodetector, an optical diode, and a modulator.

In a process in which the optical signal is input to a PIC, the photodetector may detect the optical signal input to the PIC. The optical signal may be detected by the photodetector and converted into an electrical signal. The electrical signal converted by the photodetector may be transferred to a plurality of devices of the second substrate 223B.

In a process in which the PIC outputs the optical signal, the plurality of devices of the second substrate 223B may transfer the electrical signal to the modulator. The modulator may input a signal to light emitted from an optical diode according to the electrical signal (e.g., modulate the emitted light according to the electrical signal) to convert the electrical signal into an optical signal.

In some implementations, the second optical waveguide 221 may be optically connected to the interposer optical waveguide 315. In this case, the second optical waveguide 221 and the interposer optical waveguide 315 may be connected to each other via evanescent coupling, but the coupling is not limited thereto. For example, the second optical waveguide 221 and the interposer optical waveguide 315 may also be connected to each other via edge coupling and grating coupling.

In FIG. 2, the second optical-electrical converter 222 is shown to be buried in the second insulating layer 223A, but the arrangement of the second optical-electrical converter 222 is not limited thereto, and, for example, the second optical-electrical converter 222 may be covered by an oxide layer separated from the second insulating layer 223A. For example, an oxide layer may be formed at one side of the second insulating layer 223A, and the second optical-electrical converter 222 may be located inside the oxide layer.

The first photonics chip 210 and the second photonics chip 220 may have substantially the same configuration, but are not limited thereto. The third photonics chip 230 may also have substantially the same configuration as the first photonics chip 210 and second photonics chip 220 described above.

In FIG. 2, the arrow indicates a path along which an optical signal moves. However, the signal path is not limited thereto, and the optical signal may proceed in a reverse direction of the arrow.

In some implementations, the first optical-electrical converter 212 may receive an electrical signal from the first semiconductor chip 110 (as described with respect to FIGS. 1-2) and convert the electrical signal into an optical signal. The optical signal converted from the first optical-electrical converter 212 may be output from the first optical waveguide 211 and input to the interposer optical waveguide 315. The optical signal input to the interposer optical waveguide 315 may move along the interposer optical waveguide 315 on an upper surface of the interposer 310 in a horizontal direction. Then, the optical signal may be output from the interposer optical waveguide 315 and input to the second optical waveguide 221. The optical signal input to the second optical waveguide 221 may be converted into an electrical signal by the second optical-electrical converter 222. The electrical signal converted from the second optical-electrical converter 222 may be transferred to the second semiconductor chip 120.

In FIG. 2, the optical signal output from the first photonics chip 210 is shown to be input to the second photonics chip 220 through the interposer optical waveguide 315, but the scope of this disclosure is not limited thereto. For example, an optical signal output from the second photonics chip 220 may be input to the first photonics chip 210 through the first photonics chip 210. Generally, the first photonics chip 210, the second photonics chip 220, and the third photonics chip 230 (refer to FIG. 1) may transmit and/or receive optical signals to and/or from each other through the interposer optical waveguide 315.

In some implementations, the electrical signal converted from the first photonics chip 210, the second photonics chip 220, and the third photonics chip 230 (refer to FIG. 1) may be transferred to the interposer 310 through the first lower connection pad 240.

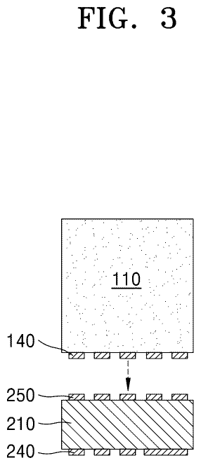

FIGS. 3 to 7 are schematic cross-sectional views illustrating an example of a method of manufacturing a semiconductor package, according to some implementations. It will be understood that the semiconductor packages described herein may be manufactured according to other methods than that described with respect to FIGS. 3 to 7.

Referring to FIG. 3, the first semiconductor chip 110 may be attached to the first photonics chip 210. The first semiconductor chip 110 may be attached to the first photonics chip 210 using a flip chip method, but the attachment is not limited thereto. In this case, the first photonics chip 210 may include a PIC and the first optical waveguide 211 based on a photonics fabrication process. The lower pad 140 of the first semiconductor chip 110 and the first upper connection pad 250 of the first photonics chip 210 may be electrically and physically connected to each other through the plurality of first connection terminals CT1.

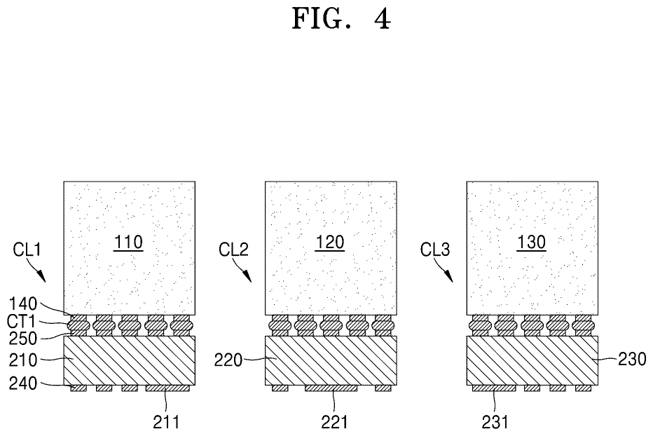

Referring to FIG. 4, the process of FIG. 3 may be repeatedly performed to form the first chiplet CL1, the second chiplet CL2, and the third chiplet CL3. The first chiplet CL1 may include first semiconductor chip 110 and the first photonics chip 210, the second chiplet CL2 may include the second semiconductor chip 120 and the second photonics chip 220, and the third chiplet CL3 may include the third semiconductor chip 130 and the third photonics chip 230.

Referring to FIGS. 3 and 4, the described method of manufacturing the semiconductor package 1 may improve the yield of the semiconductor package 1 by attaching one photonics chip per semiconductor chip. It may be possible to effectively detect defects by individually inspecting each small-sized photonics chip (e.g., the first photonics chip 210 to the third photonics chip 230). In some implementations, mass production of the semiconductor package 1 may be improved.

The first photonics chip 210, the second photonics chip 220, and the third photonics chip 230 that each include the PIC and the EIC may have high process complexity and process costs compared with other semiconductor chips. Accordingly, in some implementations, each small-sized photonics chip may be attached to a semiconductor chip individually, thereby reducing defects in photonics chips and improving the yield of the photonics chips. However, in some implementations, the photonics chips are not attached individually.

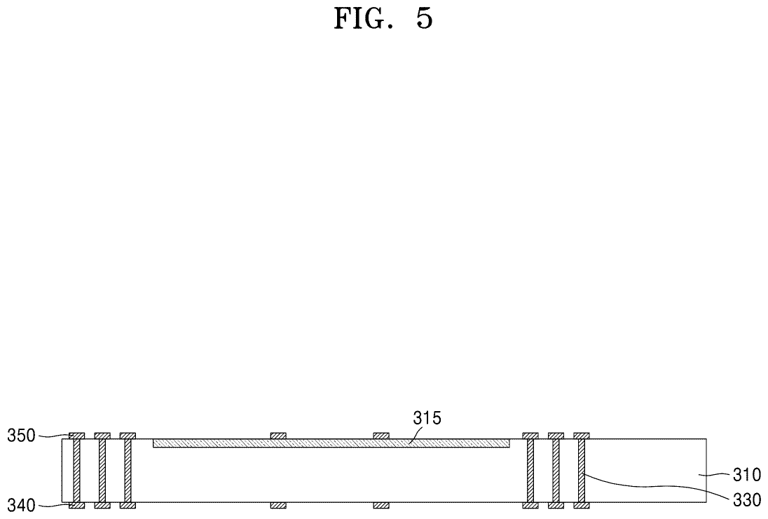

Referring to FIG. 5, the interposer 310 may be prepared. The interposer 310 may include an interposer optical waveguide 315. The interposer optical waveguide 315 may be formed at an upper end of the interposer 310. In some implementations, the interposer 310 may include a glass substrate, and the interposer optical waveguide 315 may include an ionic injection optical waveguide.

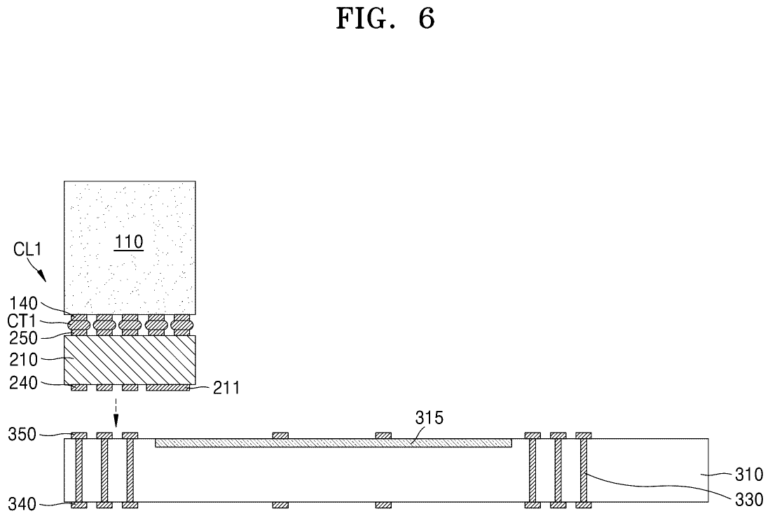

Referring to FIG. 6, the first chiplet CL1 may be attached to the interposer 310. In some implementations, the first chiplet CL1 may be attached to the interposer 310 using a flip chip method, but implementations are not limited thereto.

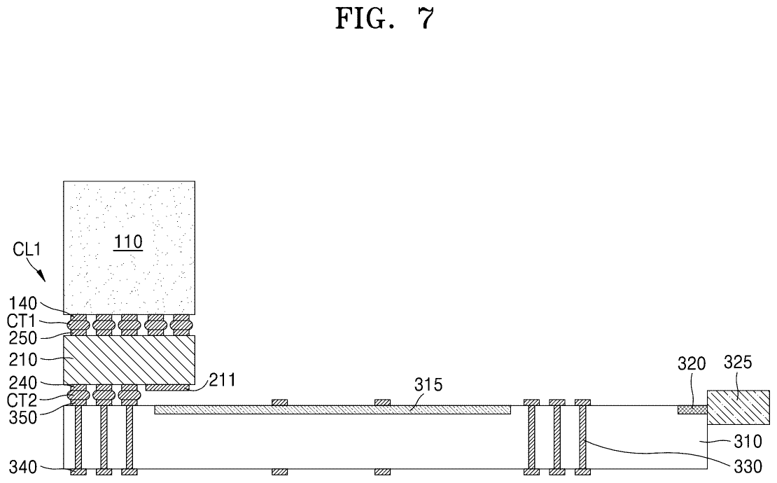

Referring to FIG. 7, the plurality of second upper connection pads 350 may be connected to the first chiplet CL1 through the plurality of second connection terminals CT2. The interposer 310 may be electrically and physically connected to the first chiplet CL1 through the plurality of second upper connection pads 350. In this case, the first optical waveguide 211 and the interposer optical waveguide 315 may be optically coupled to each other.

Then, the aforementioned processes of FIGS. 6 and 7 may be repeatedly performed to attach the second chiplet CL2 and the third chiplet CL3 to the interposer 310. The plurality of second upper connection pads 350 may be connected to the second chiplet CL2 through the plurality of second connection terminals CT2. The plurality of second upper connection pads 350 may be connected to the third chiplet CL3 through the plurality of second connection terminals CT2. The interposer 310 may be electrically and physically connected to the second chiplet CL2, and the third chiplet CL3 through the plurality of second upper connection pads 350. In this case, the second optical waveguide 221 and the interposer optical waveguide 315 may be optically coupled to each other, and the third optical waveguide 231 and the interposer optical waveguide 315 may be optically coupled to each other.

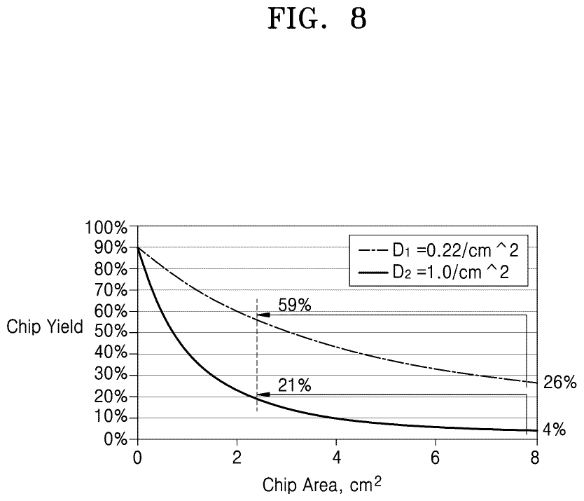

FIG. 8 is a graph illustrating an effect of a semiconductor package according to some implementations.

Referring to FIG. 8, a relationship between an area of a photonics chip and a yield of the photonics chip may be seen. It may be seen that, when the number of detects per unit area is 0.22 (D₁), if an area of the photonics chip is about 8 cm², a yield of the photonics chip is 26%. In contrast, it may be seen that, when the number of detects per unit area is 0.22 (D₁), if an area of the photonics chip is about 2.3 cm², a yield of the photonics chip is 59%. That is, it may be seen that, as an area of the photonics chip is reduced under a condition of the same number of defects per unit area, a yield of the photonics chip increases.

It may be seen that, when the number of detects per unit area is 1.0 (D₂), if an area of the photonics chip is about 8 cm², a yield of the photonics chip is 4%. In contrast, it may be seen that, when the number of detects per unit area is 1.0 (D₂), if an area of the photonics chip is about 2.3 cm², a yield of the photonics chip is 21%. That is, it may be seen that, as an area of the photonics chip is reduced under a condition of the same number of defects per unit area, a yield of the photonics chip increases.

In the method of manufacturing the semiconductor package 1 according to some implementations, one photonics chip may be attached to each semiconductor chip, thereby miniaturizing the size of the photonics chip. Accordingly, each small-sized photonics chip may be attached to a semiconductor chip individually, thereby reducing defects in photonics chips and improving the yield of the photonics chips.

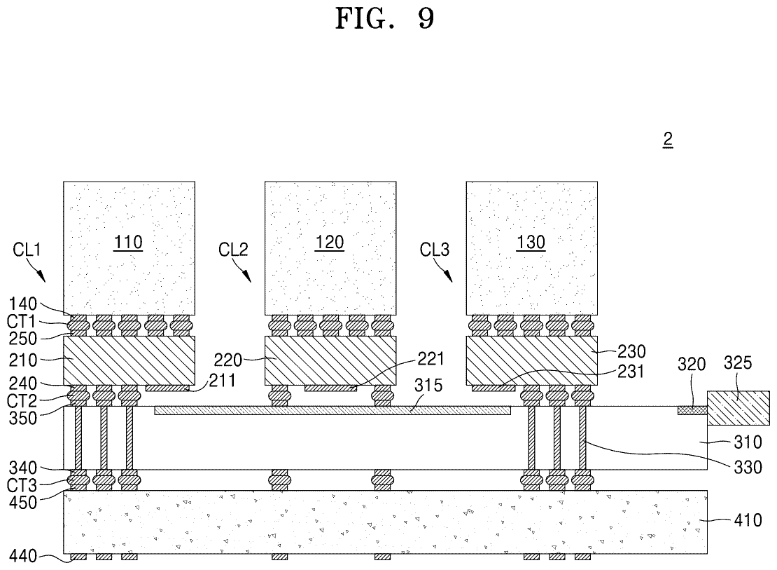

FIG. 9 is a side view illustrating a semiconductor package according to some implementations.

Referring to FIG. 9, a semiconductor package 2 according to some implementations may include the first chiplet CL1, the second chiplet CL2, the third chiplet CL3, the interposer 310, and a package substrate 410. In explaining the semiconductor package 2 of FIG. 9, common descriptions with the description given with reference to FIGS. 1 to 8 will be omitted.

The first chiplet CL1, the second chiplet CL2, and the third chiplet CL3 may be attached onto the interposer 310. The first chiplet CL1 may include a first semiconductor chip 110 and a first photonics chip 210. The first photonics chip 210 may include the first optical waveguide 211, and the first optical waveguide 211 may be optically coupled to the interposer optical waveguide 315.

The second chiplet CL2 may include the second semiconductor chip 120 and the second photonics chip 220. The second photonics chip 220 may include the second optical waveguide 221, and the second optical waveguide 221 may be optically coupled to the interposer optical waveguide 315. The third chiplet CL3 may include the third semiconductor chip 130 and the third photonics chip 230. The third photonics chip 230 may include the third optical waveguide 231, and the third optical waveguide 231 may be optically coupled to the interposer optical waveguide 315. The interposer 310 may be attached onto the package substrate 410.

The package substrate 410 may be, for example, a printed circuit board (PCB). The package substrate 410 may include at least one material selected from phenol resin, epoxy resin, and polyimide. For example, the package substrate 410 may include, for example, at least one material selected from polyimide, flame retardant 4 (FR-4), tetrafunctional epoxy, polyphenylene ether, epoxy/polyphenylene oxide, bismaleimide triazine (BT), thermount, cyanate ester, and liquid crystal polymer.

The package substrate 410 may include a plurality of third upper connection pads 450, a plurality of third lower connection pads 440, and a through via (e.g., connecting the plurality of third upper connection pads 450 to the plurality of third lower connection pads 440). The plurality of third upper connection pads 450 may be connected to the plurality of second lower connection pads 340 through a plurality of third connection terminals CT3. The package substrate 410 may be electrically and physically connected to the interposer 310 through the plurality of third upper connection pads 450.

An external connection terminal configured to electrically and physically connect the package substrate 410 to an external device may be attached to the plurality of third lower connection pads 440.

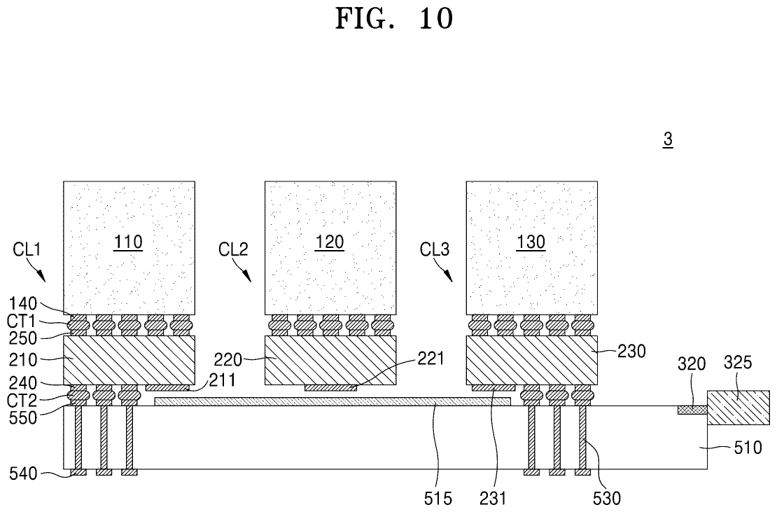

FIG. 10 is a side view illustrating a semiconductor package according to some implementations.

Referring to FIG. 10, a semiconductor package 3 according to some implementations may include the first chiplet CL1, the second chiplet CL2, the third chiplet CL3, and an interposer 510. In explaining the semiconductor package 3 of FIG. 10, common descriptions with the description given with reference to FIGS. 1 to 8 will be omitted.

The first chiplet CL1, the second chiplet CL2, and the third chiplet CL3 may be attached onto the interposer 510. The first chiplet CL1 may include the first semiconductor chip 110 and the first photonics chip 210. The first photonics chip 210 may include the first optical waveguide 211, and the first optical waveguide 211 may be optically coupled to an interposer optical waveguide 515.

The second chiplet CL2 may include the second semiconductor chip 120 and the second photonics chip 220. The second photonics chip 220 may include the second optical waveguide 221, and the second optical waveguide 221 may be optically coupled to the interposer optical waveguide 515. The third chiplet CL3 may include the third semiconductor chip 130 and the third photonics chip 230. The third photonics chip 230 may include the third optical waveguide 231, and the third optical waveguide 231 may be optically coupled to the interposer optical waveguide 515.

In some implementations, the interposer 510 may include a substrate, and the substrate may include silicon. In this case, the interposer optical waveguide 515 may include a silicon optical waveguide, but the interposer optical waveguide 515 is not limited thereto. The interposer optical waveguide 515 may be formed on an upper surface of the interposer 510. For example, the interposer optical waveguide 515 may be formed on the upper surface of the interposer 510 through a photonics fabrication process.

Although examples have been described with reference to the attached drawings, it will be appreciated by those skilled in the art that implementations according to the present disclosure may be practiced in other detailed forms without departing from the scope of this disclosure. Accordingly, it should therefore be understood that the implementations described above are exemplary and non-limiting in all respects.

While this disclosure contains many specific implementation details, these should not be construed as limitations on the scope of what may be claimed. Certain features that are described in this disclosure in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination.

While various examples been particularly shown and described, it will be understood that various changes in form and details may be made therein without departing from the spirit and scope of the following claims.

What is claimed is:

1. A semiconductor package comprising:
an interposer including an interposer optical waveguide; and
a plurality of chiplets coupled onto the interposer, wherein each chiplet of the plurality of chiplets includes a semiconductor chip and a photonics chip electrically coupled to the semiconductor chip, and
wherein the photonics chip of each chiplet includes
a photonic integrated circuit configured to input, output, or both input and output optical signals, and
an optical waveguide optically coupled to the interposer optical waveguide.

2. The semiconductor package of claim 1, wherein the optical waveguide of a first chiplet of the plurality of chiplets is coupled to the interposer optical waveguide via evanescent coupling.

3. The semiconductor package of claim 1, wherein the plurality of chiplets includes a first chiplet including a first photonics chip and a second chiplet including a second photonics chip,
wherein the first photonics chip includes a first photonic integrated circuit and a first optical waveguide, and wherein the second photonics chip includes a second photonic integrated circuit and a second optical waveguide, and
wherein the first photonics chip is configured to output a first optical signal sequentially through the first optical waveguide, the interposer optical waveguide, and the second optical waveguide.

4. The semiconductor package of claim 1, wherein the photonic integrated circuit of a first chiplet of the plurality of chiplets includes an optical-electrical converter configured to convert an optical signal into an electrical signal, convert an electrical signal into an optical signal, or both.

5. The semiconductor package of claim 1, wherein the interposer includes a glass substrate, and
wherein the interposer optical waveguide includes an ionic injection optical waveguide.

6. The semiconductor package of claim 5, wherein the interposer optical waveguide is buried in the interposer.

7. The semiconductor package of claim 1, wherein the interposer includes a silicon substrate.

8. The semiconductor package of claim 1, wherein the plurality of chiplets are spaced apart from one another in a direction parallel to a surface of the interposer.

9. The semiconductor package of claim 1, wherein a lateral area of each of the plurality of chiplets is less than a lateral area of the interposer.

10. The semiconductor package of claim 9, wherein the interposer optical waveguide is disposed on an upper surface of the interposer.

11. The semiconductor package of claim 1, wherein the optical waveguide of a first chiplet of the plurality of chiplets and the interposer optical waveguide are disposed to face each other.

12. The semiconductor package of claim 1, wherein the photonics chip of a first chiplet of the plurality of chiplets includes an electronic integrated circuit configured to electrically connect the semiconductor chip and the photonic integrated circuit to each other.

13. A method of manufacturing a semiconductor package, the method comprising:
attaching a first semiconductor chip to a first photonics chip to obtain a first chiplet, wherein the first photonic chip includes a first photonic integrated circuit and a first optical waveguide;
attaching a second semiconductor chip to a second photonics chip to obtain a second chiplet, wherein the second photonics chip includes a second photonic integrated circuit and a second optical waveguide; and
attaching the first chiplet and the second chiplet to an interposer, wherein the interposer includes an interposer optical waveguide.

14. The method of claim 13, wherein attaching the first chiplet and the second chiplet to the interposer comprises:
attaching the first chiplet to the interposer to optically couple the first optical waveguide and the interposer optical waveguide to one another; and
attaching the second chiplet to the interposer to optically couple the second optical waveguide and the interposer optical waveguide to one another.

15. The method of claim 14, wherein the first optical waveguide is coupled to the interposer optical waveguide via evanescent coupling, and
wherein the second optical waveguide is coupled to the interposer optical waveguide via evanescent coupling.

16. The method of claim 13, comprising forming the interposer optical waveguide in the interposer using an ion injection process.

17. The method of claim 16, wherein the interposer optical waveguide is buried in the interposer.

18. A semiconductor package comprising:
an interposer including an interposer optical waveguide;
a first chiplet attached to the interposer and including a first semiconductor chip and a first photonics chip electrically coupled to the first semiconductor chip; and
a second chiplet attached to the interposer and including a second semiconductor chip and a second photonics chip electrically coupled to the second semiconductor chip,
wherein the first photonics chip includes:
a first photonic integrated circuit configured to convert signals between electrical signals and optical signals,
a first electronic integrated circuit that electrically connects the first semiconductor chip and the first photonic integrated circuit to each other, and
a first optical waveguide optically coupled to the interposer optical waveguide, and
wherein the second photonics chip includes:
a second photonic integrated circuit configured to convert signals between electrical signals and optical signals,
a second electronic integrated circuit that electrically connects the second semiconductor chip and the second photonic integrated circuit, and
a second optical waveguide optically coupled to the interposer optical waveguide.

19. The semiconductor package of claim 18, wherein a lateral area of the first photonics chip is less than a lateral area of the interposer, and
wherein a lateral area of the second photonics chip is less than the lateral area of the interposer.

20. The semiconductor package of claim 18, comprising an optical fiber coupled to the interposer and configured to transmit, receive, or both transmit and receive optical signals to or from the interposer.
